(19) United States
(12) Patent Application Publication
(10) Pub. No.: US 2026/0353756 A1
(43) Pub. Date: Nov. 5, 2026

(54) SEMICONDUCTOR DEVICE AND METHOD FOR MANUFACTURING THE SAME

(71) Applicant: Mitsubishi Electric Corporation, Tokyo (JP)

(72) Inventor: Koichiro NISHIZAWA, Tokyo (JP)

(73) Assignee: Mitsubishi Electric Corporation, Tokyo (JP)

(21) Appl. No.: 19/121,333

(22) PCT Filed: Mar. 10, 2023
(86) PCT No.: PCT/JP2023/009363

§ 371 Date: Apr. 15, 2025

(51) Int. Cl. H10D 64/62; H10D 64/01

(52) U.S. Cl. CPC H10D 64/62; H10D 64/0116

(57) ABSTRACT

A barrier metal (2) made of a metal material co-deposited with phosphorus or boron is formed on a semiconductor substrate (1). Aa copper film (3) is formed on the barrier metal (2). The barrier metal (2) includes a first barrier metal (2a) in contact with the semiconductor substrate (1) and a second barrier metal (2b) formed on the first barrier metal (2a). The first barrier metal (2a) and the second barrier metal (2b) are formed of the same material. The first barrier metal (2a) is polycrystalline. The second barrier metal (2b) has an amorphous structure.

### FIELD

The present disclosure relates to a semiconductor device and a method for manufacturing the same.

### BACKGROUND

III-V group semiconductor devices such as GaAs are used in communication devices and the like. As an electrode material for the semiconductor device, copper or the like is used, which has high electrical conductivity. However, copper diffuses into a semiconductor substrate and deteriorates the characteristics of the semiconductor device. Therefore, a barrier metal is formed between the semiconductor substrate and the copper film. In order to improve the adhesion between the semiconductor substrate and the barrier metal, a heat treatment is performed to diffuse the metal atoms of the barrier metal into the semiconductor substrate, thereby forming a diffusion layer between the barrier metal and the semiconductor substrate. It is known that the barrier metal is formed by nickel electroless plating (see, for example, PTL 1).

### CITATION LIST

### Patent Literature

[PTL 1] JP 2020-100869 A

### SUMMARY OF THE INVENTION

### Problem to be Solved by the Invention

When phosphorus or boron is co-deposited with nickel electroless plating film, an amorphous structure is formed, which enhances the barrier properties against copper diffusion. However, when nickel in the plating film diffuses into the semiconductor substrate due to heat treatment or the operating environment, the concentration of phosphorus or boron in the plating film increases. As a result, the plating film crystallizes and grain boundaries are generated, which causes a problem of deteriorated barrier properties against copper diffusion.

This disclosure has been made to solve the problem described above, and an object thereof is to obtain a semiconductor device and a method for manufacturing the same that can obtain high barrier properties against copper diffusion.

### Solution to Problem

A semiconductor device according to the present disclosure includes: a semiconductor substrate; a barrier metal made of a metal material co-deposited with phosphorus or boron and formed on the semiconductor substrate; and a copper film formed on the barrier metal, wherein the barrier metal includes a first barrier metal in contact with the semiconductor substrate and a second barrier metal formed on the first barrier metal, the first barrier metal and the second barrier metal are formed of the same material, the first barrier metal is polycrystalline, and the second barrier metal has an amorphous structure.

### Advantageous Effects of Invention

In the present disclosure, since the second barrier metal has an amorphous structure, there can be obtained a high barrier properties against the diffusion of copper atoms of the copper film.

### BRIEF DESCRIPTION OF THE DRAWINGS

FIG. 1 is a cross-sectional view showing a semiconductor device according to a first embodiment.

FIG. 2 is a cross-sectional view showing a method for manufacturing a semiconductor device according to the first embodiment.

FIG. 3 is a cross-sectional view showing a method for manufacturing a semiconductor device according to a comparative example.

FIG. 4 is a cross-sectional view showing a method for manufacturing a semiconductor device according to a comparative example.

FIG. 5 is a cross-sectional view showing a semiconductor device according to a second embodiment.

FIG. 6 is a cross-sectional view showing a method for manufacturing a semiconductor device according to the second embodiment.

FIG. 7 is a cross-sectional view showing a method for manufacturing a semiconductor device according to the second embodiment.

FIG. 8 is a cross-sectional view showing a method for manufacturing a semiconductor device according to the second embodiment.

### DESCRIPTION OF EMBODIMENTS

A semiconductor device and a method for manufacturing the same according to the embodiments of the present disclosure will be described with reference to the drawings. The same components will be denoted by the same symbols, and the repeated description thereof may be omitted.

### First Embodiment

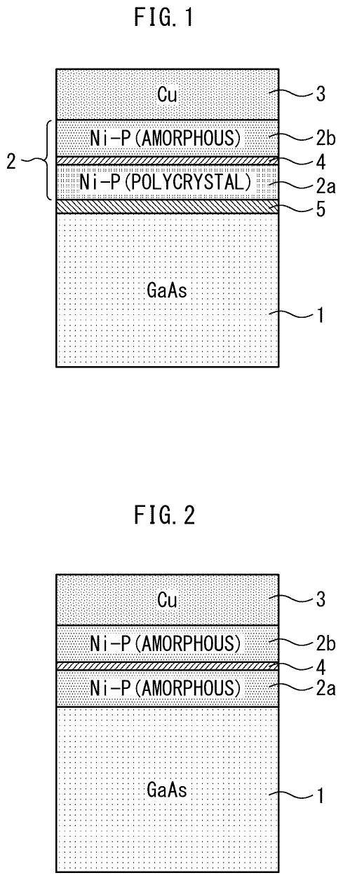

FIG. 1 is a cross-sectional view showing a semiconductor device according to a first embodiment. A semiconductor substrate 1 is made of a III-V group semiconductor such as GaAs. A barrier metal 2 made of a metal material co-deposited with phosphorus (P) or boron (B) is formed on the semiconductor substrate 1. A copper film 3 is formed on the barrier metal 2.

The barrier metal 2 is, for example, a nickel alloy co-deposited with phosphorus (Ni—P). Here, Ni—P stands for an alloy of nickel and phosphorus, and hyphens will be used in the same manner to represent alloys in the following description. The barrier metal 2 is not limited to this, and may be any alloy in which phosphorus or boron is co-deposited with at least one of nickel (Ni), cobalt (Co), and tungsten (W). In other words, the barrier metal 2 can be any of Ni—P, Ni—W—P, Ni—Co—P, Co—P, Co—W—P, Ni—B, Ni—W—B, Ni—Co—B, Co—B, or Co—W—B. These alloys can be formed by electroless plating and have high barrier properties against the diffusion of copper (Cu) from the copper film 3. The crystallinity of the barrier metal 2 can be controlled by the solution composition or treatment conditions.

The barrier metal 2 includes a first barrier metal 2a in contact with the semiconductor substrate 1 and a second barrier metal 2b formed on the first barrier metal 2a. The diffusion prevention layer 4 is formed between the first barrier metal 2a and the second barrier metal 2b. The diffusion prevention layer 4 contains at least one of gold (Au), silver (Ag), copper (Cu), palladium (Pd), platinum (Pt), titanium (Ti), and aluminum (Al). The diffusion prevention layer 4 made of these materials can prevent the diffusion of nickel, cobalt or tungsten, which are the metal materials of the second barrier metal 2b, and has high adhesion to nickel alloys, cobalt alloys, or tungsten alloys.

The internal stress and linear expansion amount of the metal film are determined by the material. Therefore, the first barrier metal 2a and the second barrier metal 2b are formed of the same material. This reduces the stress that occurs at the interface due to the difference in internal stress or linear expansion amount between the two, and prevents interface peeling caused by stress.

The metal material of the first barrier metal 2a diffuses into the semiconductor substrate 1, forming a diffusion layer 5 between the first barrier metal 2a and the semiconductor substrate 1. The diffusion layer 5 has higher adhesion to the barrier metal 2 and the semiconductor substrate 1 than the sputtered film and the evaporated film. Therefore, the formation of the diffusion layer 5 can improve the adhesion between the semiconductor substrate 1 and the barrier metal 2.

The first barrier metal 2a is a polycrystal such as Ni₃P, Ni₁₂P₅, or Ni—P₃. The polycrystalline grains are nanoscale. In contrast, the second barrier metal 2b is not polycrystalline but has a uniform amorphous structure. In the amorphous structure, phosphorus or boron is present between the lattices of nickel crystals and distorts the crystals.

Next, a method for manufacturing a semiconductor device according to this embodiment will be described. FIG. 2 is a cross-sectional view showing a method for manufacturing a semiconductor device according to the first embodiment. First, hydrophilization and activator treatment are performed as pretreatment. For example, oxygen plasma treatment or ozone treatment is performed to modify the surface of the semiconductor substrate 1 to be hydrophilic. When the semiconductor substrate 1 is then immersed in an active solution for electroless plating reaction containing Pd ions, the surface of the semiconductor substrate 1 dissolves due to the effect of galvanic corrosion, and Pd is deposited. For example, the Pd ion concentration is 10 ppm to 100 ppm, the liquid temperature is 0 °C to 50 °C, and the immersion time is 1 to 5 minutes. If the amount of Pd deposition is too small, the Ni plating film that is subsequently formed will not be formed, and if it is too large, the adhesion between the films will deteriorate. However, since the ease of Pd deposition differs depending on the type of semiconductor, adjustment is needed generally within the above range depending on the type of substrate.

After the pretreatment is completed, the semiconductor substrate 1 is immersed in an electroless Ni plating solution containing hypophosphorous acid as a main component. For example, the liquid temperature is 70 °C to 90 °C. By circulating, filtering, and rocking the solution, the plating reaction can be stabilized, and therefore the plating film can be formed smoothly. Ni ions become Ni and are deposited by the catalytic action of Pd, and P, a liquid component, is co-deposited to form a Ni—P alloy film. Here, Pd is used as an example of the catalytic metal, but a Ni alloy film can be obtained in the same manner with any metal having catalytic activity for electroless plating deposition, such as Au, Ag, Pt, Ni, Sn, or Ru. In this way, the first barrier metal 2a with an amorphous structure is formed on the semiconductor substrate 1 by electroless plating. Note that the first barrier metal 2a may be formed by other means such as PVD or vapor deposition. In this case, the step of depositing a metal having catalytic activity such as Pd is not necessary as pretreatment.

The wafer is taken out from the electroless Ni plating solution and washed with water, and then immersed in an electroless Pd plating solution while being left wet, thereby forming the diffusion prevention layer 4 on the first barrier metal 2a. The thickness of the diffusion prevention layer 4 is, for example, 0.01 μm. If the thickness is thicker than 0.1 μm, peeling will occur at the boundary with the first barrier metal 2a, and the thickness is therefore designed to be 0.1 μm or less. If the thickness is less than 0.01 μm, deposition is not stable, and the thickness is therefore designed to be 0.01 μm or more. The material of the diffusion prevention layer 4 is not limited to Pd, and other materials may be used as long as they can prevent interdiffusion.

For example, there can be used plating of a metal having catalytic activity for electroless plating deposition, such as Au, Ag, Pt, Sn, or Ru. In addition, electroless plating is a simple and easy-to-use method for forming the diffusion prevention layer 4, but sputtering or vapor deposition may also be used.

Next, the second barrier metal 2b with an amorphous structure is formed on the diffusion prevention layer 4 by electroless plating. The method for forming the second barrier metal 2b is the same as the method for forming the first barrier metal 2a.

The wafer and copper plate are then immersed in a copper sulfate plating solution, and electricity is applied with the outer periphery of the wafer as the cathode and the copper plate as the anode, thereby forming a copper film 3 on the second barrier metal 2b in proportion to the amount of electricity supplied. For example, the liquid temperature is 30 °C. Note that electroless plating can also be used instead of electroplating. Also in the case of electroless plating, the copper film 3 can be formed by adjusting the additives. In order to prevent surface oxidation of the copper film 3, Ni plating, Pd plating, and Au plating can be performed in sequence in post-treatment by electroless plating or electroplating. This improves the adhesion of die bonding or wire bonding.

The first barrier metal 2a and the second barrier metal 2b are made of the same material, for example, Ni—P film. When the Ni—P film is formed with a P concentration of 10 at % to 25 at %, the film has an amorphous structure. For this reason, the first barrier metal 2a and second barrier metal 2b to be formed are made to have a co-deposition amount of phosphorus or boron of 10 at % or more to have an amorphous structure.

Next, heat treatment is performed at 150 °C to 300 °C. As a result, the metal material of the first barrier metal 2a diffuses into the semiconductor substrate 1, forming a diffusion layer 5 between the first barrier metal 2a and the semiconductor substrate 1. The first barrier metal 2a, the metal material of which has diffused into the semiconductor substrate 1, crystallizes due to increase in the co-deposition of P or B. In contrast, the diffusion prevention layer 4 prevents the diffusion of metal atoms in the second barrier metal 2b, so that the second barrier metal 2b maintains an amorphous structure without any change in film composition also after heat treatment. Therefore, the second barrier metal 2b has high barrier properties against the diffusion of copper atoms of the copper film 3.

Note that while the interface between the semiconductor substrate 1 and the barrier metal 2 is in a poor state, application of heat may cause peeling. For this reason, the heat treatment can be used as a pre-screening for defective products before shipment.

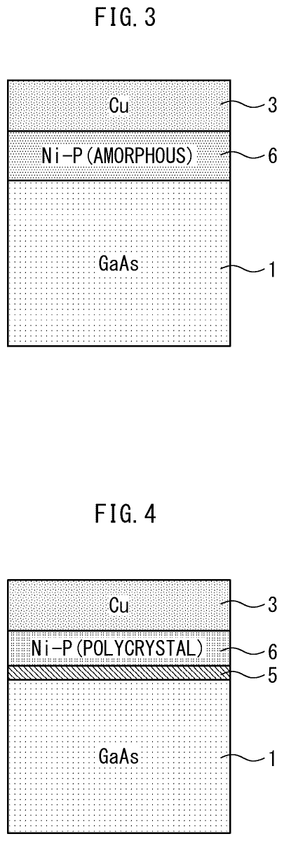

Next, the effect of this embodiment will be described by comparing it with a comparative example. FIGS. 3 and 4 are cross-sectional views showing a method for manufacturing a semiconductor device according to a comparative example. As shown in FIG. 3, a layer of barrier metal 6 is formed on the semiconductor substrate 1, and a copper film 3 is formed on top of that. The barrier metal 6 has an amorphous structure when being formed. Next, when a heat treatment is performed at 150 °C to 300 °C, the metal atoms of the barrier metal 6 diffuse into the semiconductor substrate 1, forming a diffusion layer 5, as shown in FIG. 4. The barrier metal 6, the metal atoms of which have diffused, entirely crystallizes because the co-deposition of phosphorus or boron increases. Therefore, the barrier metal 6 after heat treatment has deteriorated barrier properties against diffusion of copper atoms of the copper film 3.

In contrast, in this embodiment, the diffusion prevention layer 4 prevents the diffusion of metal atoms in the second barrier metal 2b, so that the second barrier metal 2b does not crystallize also after heat treatment. Since the second barrier metal 2b has an amorphous structure, there can be obtained a high barrier properties against the diffusion of copper atoms of the copper film 3. In addition, the nickel diffusion layer 5 is thinner than when the barrier metal is a single layer of nickel alloy, so that the stress caused by the diffusion layer 5 is reduced.

The thickness of the barrier metal 2 needs to be 0.1 μm or more to provide a barrier properties against the diffusion of copper atoms. However, if the barrier metal 2 is thicker than 0.5 μm, the device will bend due to stress. Therefore, the film thickness of the barrier metal 2 is set to 0.1 μm or more and 0.5 μm or less.

### Second Embodiment

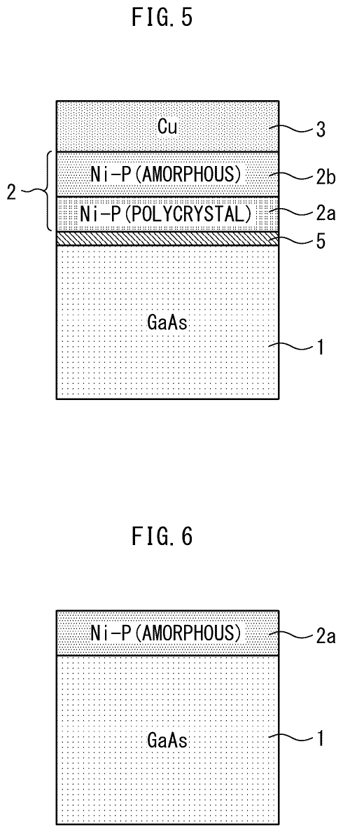

FIG. 5 is a cross-sectional view showing a semiconductor device according to a second embodiment. The difference from the first embodiment is that there is no diffusion prevention layer 4, and the second barrier metal 2b is formed directly on the first barrier metal 2a. The other configurations are the same as those of the first embodiment.

Next, a method for manufacturing a semiconductor device according to this embodiment will be described. FIGS. 6 to 8 are cross-sectional views showing a method for manufacturing a semiconductor device according to the second embodiment. First, as shown in FIG. 6, the first barrier metal 2a is formed on the semiconductor substrate 1 by electroless plating. At this stage, the first barrier metal 2a has an amorphous structure.

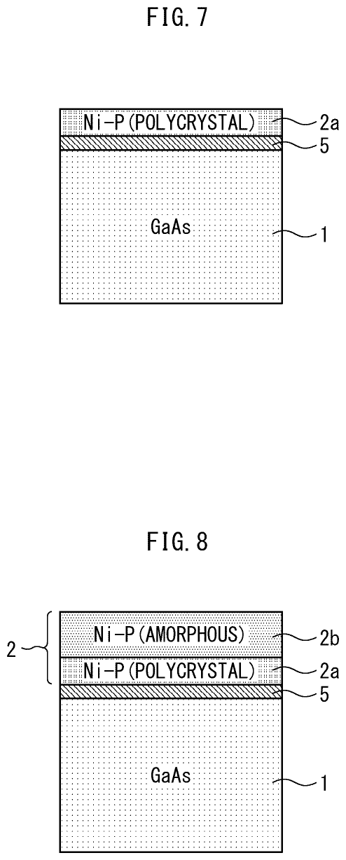

Next, as shown in FIG. 7, a heat treatment at 150 °C to 300 °C is performed to diffuse the metal atoms of the first barrier metal 2a into the semiconductor substrate 1, forming a diffusion layer 5 between the first barrier metal 2a and the semiconductor substrate 1. The first barrier metal 2a after heat treatment is polycrystalline. In addition, a depth analysis has demonstrated that the P concentration in the Ni—P film is uniform in the film also after Ni diffusion. Therefore, the concentration of the metal material and co-deposition of the first barrier metal 2a after heat treatment are uniform in the film.

Next, as shown in FIG. 8, a second barrier metal 2b is formed directly on the first barrier metal 2a by electroless plating. The first barrier metal 2a and the second barrier metal 2b are formed of the same material. If the first barrier metal 2a forms a polycrystal, the elements of the two layers will not interdiffuse even if a second barrier metal 2b made of the same Ni and P is laminated on top of the first barrier metal 2a. This is because the polycrystalline Ni—P crystal structure of the first barrier metal 2a is energetically more stable than amorphous structure and is less likely to change structurally. The second barrier metal 2b has an amorphous structure.

Amorphous Ni-P films with low phosphorus concentration (10 at % to 25 at %) do not crystallize when being heated to 300 °C or less. Therefore, the second barrier metal 2 b maintains an amorphous structure in a heat treatment or use environment of 300 °C or less.

Then, a copper film 3 is formed on the second barrier metal 2b by electroless plating, thereby manufacturing the semiconductor device shown in FIG. 5.

In this embodiment, after the first barrier metal 2a is formed, a heat treatment is performed before the second barrier metal 2b is formed, so that the second barrier metal 2b remains in an amorphous structure. This can provide a high barrier properties against the diffusion of copper atoms in the copper film 3. In addition, the step of forming the diffusion prevention layer 4 between the first barrier metal 2a and the second barrier metal 2b is not necessary.

Furthermore, the diffusion layer 5 can be made thinner than when the barrier metal is formed in a single layer. Since the diffusion layer 5 has high stress, making the diffusion layer 5 thin can reduce the stress. In addition, since the first barrier metal 2a and the second barrier metal 2b are made of the same material, they have high adhesion to each other.

### REFERENCE SIGNS LIST

1 semiconductor substrate; 2 barrier metal; 2a first barrier metal; 2b second barrier metal; 3 copper film; 4 diffusion prevention layer; 5 diffusion layer

1. A semiconductor device comprising:
a semiconductor substrate;
a barrier metal made of a metal material co-deposited with phosphorus or boron and formed on the semiconductor substrate; and
a copper film formed on the barrier metal,
wherein the barrier metal includes a first barrier metal in contact with the semiconductor substrate and a second barrier metal formed on the first barrier metal,
the first barrier metal and the second barrier metal are formed of the same material,
the first barrier metal is polycrystalline, and
the second barrier metal has an amorphous structure.

2. The semiconductor device according to claim 1, wherein metal atoms of the first barrier metal diffuses into the semiconductor substrate, forming a diffusion layer between the first barrier metal and the semiconductor substrate.

3. The semiconductor device according to claim 1, wherein a film thickness of the barrier metal is 0.1 μm or more and 0.5 μm or less.

4. The semiconductor device according to claim 1, wherein the metal material contains at least one of nickel, cobalt, and tungsten.

5. The semiconductor device according to claim 1, further comprising a diffusion prevention layer formed between the first barrier metal and the second barrier metal and preventing diffusion of metal atoms in the second barrier metal.

6. The semiconductor device according to claim 5, wherein the diffusion prevention layer contains at least one of gold, silver, copper, palladium, platinum, titanium, and aluminum.

7. The semiconductor device according to claim 1, wherein the second barrier metal is formed directly on the first barrier metal.

8. A method for manufacturing a semiconductor device comprising:
forming a first barrier metal made of a metal material co-deposited with phosphorus or boron on a semiconductor substrate;
performing a heat treatment to diffuse metal atoms of the first barrier metal into the semiconductor substrate, forming a diffusion layer between the first barrier metal and the semiconductor substrate;
after the heat treatment, forming a second barrier metal directly on the first barrier metal; and
forming a copper film on the second barrier metal,
wherein the first barrier metal and the second barrier metal are formed of the same metal material,
the first barrier metal after heat treatment is polycrystalline, and
the second barrier metal has an amorphous structure.
